(19) United States
(12) Patent Application Publication
(10) Pub. No.: US 2016/0250719 A1
(43) Pub. Date: Sep. 1, 2016

(54) SOLDER TRANSFER SHEET

(71) Applicants: SENJU METAL INDUSTRY CO., LTD., Tokyo (JP); NITTA CORPORATION, Osaka (JP)

(72) Inventors: Kaichi Tsuruta, Tokyo (JP); Takeo Saitoh, Tokyo (JP); Manabu Muraoka, Tokyo (JP); Hiroki Oshima, Tokyo (JP); Koji Yamashita, Nara (JP); Tomohiro Nishio, Nara (JP); Shinichiro Kawahara, Nara (JP)

(21) Appl. No.: 15/033,963

(22) PCT Filed: Nov. 5, 2014
(86) PCT No.: PCT/JP2014/079323

§ 371 Date: May 3, 2016

(30) Foreign Application Priority Data
Nov. 5, 2013 (JP) 2013-229397

(51) Int. Cl. B23K 35/02; B23K 35/36; B23K 35/26; H05K 3/34; H01L 23/00

(52) U.S. Cl. CPC B23K 35/0238; H05K 3/3484; H01L 24/11; B23K 35/262; B23K 35/3613; H05K 2203/0425; H01L 2224/11001

(57) ABSTRACT

The present solder transfer sheet addresses the issue of providing a solder transfer sheet having both solder powder holding properties and sheet releasing properties and having excellent solder transfer properties. This solder transfer sheet is for soldering in a section to be soldered in a circuit substrate and has: a support base material; an adhesive layer provided on at least one surface of the support base material; and at least one solder layer including solder particles, provided upon the adhesive layer. The adhesive layer contains a side-chain crystalline polymer, exhibits viscosity by having fluidity at at least the melting point of the side-chain crystalline polymer, and decreases viscosity by crystalizing at temperatures less than the melting point of the side-chain crystalline polymer.

### TECHNICAL FIELD

The present invention relates to a solder transfer sheet for selectively forming solder bumps on portions of a semiconductor circuit where soldering is to be performed (hereinafter referred to as “portions to be soldered”).

### BACKGROUND ART

Along with the widespread use of portable devices and enhanced performance of electronic circuits, the electronic circuits are decreasing in size and increasing in density, and semiconductors for use in the electronic circuits are also correspondingly increasing in density.

Further, a semiconductor has conventionally been connected to a printed circuit board by a lead frame made of copper or Alloy 42, but a BGA package in which a connection is established by solder balls arranged on a rear surface of a semiconductor is mainly used, and flip chip mounting which cuts out planar space for wire bonding and forms a three-dimensional structure begins to be also widely used for connection of semiconductor internal circuits instead of wire bonding using metal wires.

Flip chip mounting involves previously forming solder bumps on a module substrate for use in a BGA package and soldering IC chips on the formed solder bumps, and is suitable to decrease the semiconductor size and increase the semiconductor density because space used in conventional wire bonding is not necessary.

In most cases, solder bumps have been formed on conventional module substrates using solder paste. However, as semiconductor circuits further decrease in size and increase in density, solder bumps for use in module substrates also have finer shapes. Therefore, this situation is addressed by solder paste using fine solder powder. However, the solder paste which is printed using a metal mask begins to reach its limit and the proportion of flip chip solder bumps formed using micro-balls which are fine solder balls with a ball diameter of 10 to 50 μm is increasing.

A flip chip bump-forming method using micro-balls can be also applied to fine solder bumps and is excellent. However, this method is defective in that it takes time to mount solder balls because the solder balls must be handled on a ball-by-ball basis and high accuracy is required to mount the solder balls. In addition, the micro-balls are expensive as compared to solder paste because of their price setting on a ball-by-ball basis and a solder bump-forming method positioned between the solder paste and the micro-balls has been desired.

Developed in response to these requests were solder powder-containing transfer sheets each obtained by forming an adhesive layer on a support (supporting substrate) made of aluminum, stainless steel, polyimide resin, plastic, glass epoxy resin or the like, and spraying solder powder (solder particles) onto the adhesive layer without gaps to adhere only one layer of the solder powder to an adhesive surface of the support, the transfer sheets being called “solder transfer sheets” (see, for example, Patent Literatures 1 and 2).

### CITATION LIST

### Patent Literature

Patent Literature 1: WO 2006/067827

Patent Literature 2: WO 2010/093031

### SUMMARY OF INVENTION

### Technical Problems

Each of the solder transfer sheets described in Patent Literatures 1 and 2 is manufactured by applying an acrylic adhesive or the like onto a support made of aluminum, stainless steel, polyimide resin, plastic, glass epoxy resin or the like to form an adhesive layer, and spraying solder powder onto the adhesive layer without gaps.

In this manufacturing step and particularly in the step of spraying the solder powder onto a surface of the adhesive layer to adhere the solder powder onto the adhesive layer (hereinafter referred to also as “solder powder adhesion step”), the adhesive layer preferably has higher adhesiveness and lack of adhesiveness in the adhesive layer causes the solder powder to come off the sheet. In the specification, adhesion or holding performance of solder powder to or in the adhesive layer is referred to as “solder powder holding properties.”

On the other hand, if the adhesiveness of the adhesive layer is too high in the step of adhering solder powder to a solder transfer sheet, when the manufactured solder transfer sheet is peeled off from a transfer target after the solder powder is transferred using the transfer sheet, the transfer sheet strongly adheres to the transfer target, which makes it difficult to peel off the transfer sheet from the transfer target easily. When the transfer sheet is forcibly peeled off, the adhesive force at the time of peeling off the transfer sheet causes damage to electrodes and the like on a surface of the transfer target. In the specification, the release performance of the transfer sheet after solder powder is transferred therefrom is referred to as “sheet release properties.”

Further, in general, an adhesive which has higher adhesiveness (in other words, which is more flexible) has the nature of lower storage modulus, whereas an adhesive which has lower adhesiveness (in other words, which is more rigid) has the nature of higher storage modulus.

Electrodes and the like on a surface of a transfer target protrude, so that in formation of, solder bumps using a solder transfer sheet, the storage modulus at the time of transfer is preferably lower and a state in which the electrodes and the like on the surface of the transfer target are wrapped with the transfer sheet is appropriate from the viewpoint that the adhesive layer follows irregularities of the electrodes and the like.

On the other hand, it is appropriate for solder powder to be embedded and constrained within the adhesive layer under pressure in order to prevent the solder powder adhering to the adhesive layer from moving on a surface of a portion of the transfer target other than the electrodes (e.g., on a solder resist), thus causing bridging between the electrodes.

Therefore, a high storage modulus causes a defect of bridging between the electrodes because the solder powder on the surface of the portion of the transfer target other than the electrodes cannot be constrained under pressure. In the specification, the properties of transferring solder powder while suppressing occurrence of bridging are referred to as “solder transfer properties.”

An object of the present invention is to provide a solder transfer sheet which allows solder powder holding properties and sheet release properties to be simultaneously achieved while exhibiting excellent solder transfer properties.

### Solution to Problems

The inventors of the present invention have made an intensive study to achieve the above-described object and as a result found that solder powder holding properties and sheet release properties can be simultaneously achieved by using in a solder transfer sheet an adhesive capable of increasing adhesiveness of an adhesive layer at a temperature in a solder powder adhesion step during manufacture and reducing adhesiveness of the adhesive layer when the solder transfer sheet is peeled off from a transfer target, and excellent solder transfer properties are achieved by using a solder transfer sheet having an adhesive applied thereto, the adhesive having a storage modulus reduced within a proper range at a temperature during transfer from the solder transfer sheet. The present invention has been thus completed.

Specifically, the inventors of the present invention have found that the foregoing object can be achieved, by the characteristic features as described below.

(1) A solder transfer sheet for soldering on portions of a circuit board to be soldered, the solder transfer sheet comprising:

a supporting substrate; an adhesive layer formed on at least one surface of the supporting substrate; and a solder layer formed on the adhesive layer and having one or more solder particle layers,

wherein the adhesive layer contains a side-chain crystalline polymer, and the adhesive layer exhibits an adhesive force when the side-chain crystalline polymer has fluidity at a melting point of the side-chain crystalline polymer or higher and the adhesive force of the adhesive layer is reduced when the side-chain crystalline polymer crystallizes at a temperature lower than the melting point of the side-chain crystalline polymer.

(2) The solder transfer sheet according to (1), wherein the side-chain crystalline polymer has the melting point of 40° C. or higher but lower than 70° C.

(3) The solder transfer sheet according to (1) or (2), wherein the side-chain crystalline polymer is a copolymer obtained by polymerizing 30 to 60 parts by weight of an acrylic acid ester or methacrylic acid ester having a straight-chain alkyl group containing 18 or more carbon atoms, 45 to 65 parts by weight of an acrylic acid ester or methacrylic acid ester having an alkyl group containing 1 to 6 carbon atoms, and 1 to 10 parts by weight of a polar monomer.

(4) The solder transfer sheet according to any one of (1) to (3), wherein the side-chain crystalline polymer has a weight-average molecular weight of 200,000 to 1,000,000.

(5) The solder transfer sheet according to any one of (1) to (4), wherein the adhesive layer has an adhesive force of 2.0 N/25 mm to 10.0 N/25 mm at the melting point of the side-chain crystalline polymer or higher.

(6) The solder transfer sheet according to any one of (1) to (5), wherein the adhesive layer has an adhesive force of less than 2.0 N/25 mm at the temperature lower than the melting point of the side-chain crystalline polymer.

(7) The solder transfer sheet according to any one of (1) to (6), wherein the adhesive layer has a storage modulus of 1×10⁴ to 1×10⁶ Pa at the melting point of the side-chain crystalline polymer or higher.

### Advantageous Effects of Invention

The present invention can provide a solder transfer sheet which allows solder powder holding properties and sheet release properties to be simultaneously achieved while exhibiting excellent solder transfer properties.

### BRIEF DESCRIPTION OF DRAWINGS

FIG. 1 is a diagram illustrating a relationship between the temperature of a side-chain crystalline polymer synthesized in Example 2 (Synthesis Example 2) and the storage modulus of an adhesive.

FIG. 2 is an electron micrograph of a solder layer surface of a solder transfer sheet prepared in Example 2 (having a filling ratio of 70% or more).

FIG. 3 is a diagram illustrating a result of a solder transfer test using the solder transfer sheet prepared in Example 2 (state in which solder is only transferred onto electrodes of silicon wafer chips).

### DESCRIPTION OF EMBODIMENTS

Next, the present invention is described in detail.

A solder transfer sheet according to the invention is a solder transfer sheet for soldering on portions of circuit board to be soldered, the solder transfer sheet including: a supporting substrate; an adhesive layer formed on at least one surface of the supporting substrate; and a solder layer formed on the adhesive layer and having one or more solder particle layers, wherein the adhesive layer contains a side-chain crystalline polymer, and the adhesive layer exhibits an adhesive force when the side-chain crystalline polymer has fluidity at a melting point of the side-chain crystalline polymer or higher and the adhesive force of the adhesive layer is reduced when the side-chain crystalline polymer crystallizes at a temperature lower than the melting point of the side-chain crystalline polymer.

The “solder transfer sheet for soldering on portions of a circuit board to be soldered” as used herein is a sheet for selectively transferring solder powder to electrodes and the like, for example as in Patent Literature 2 (WO 2010/093031), by disposing the solder transfer sheet so as to be superposed on a circuit board in such a manner that the solder transfer sheet faces the portions of the circuit board to be soldered, applying a pressure to the solder transfer sheet and the circuit board superposed on each other, and heating them under pressure to selectively cause diffusion bonding between the portions of the circuit board to be soldered and the solder layer of the transfer sheet.

The supporting substrate, the adhesive layer and the solder layer making up the solder transfer sheet according to the invention are described below in detail.

### [Supporting Substrate]

Exemplary constituent materials of the supporting substrate include synthetic resins such as polyethylene, polyethylene terephthalate, polypropylene, polyester, polyamide, polyimide, polycarbonate, ethylene-vinyl acetate copolymer, ethylene-ethyl acrylate copolymer, ethylene-polypropylene copolymer, and polyvinyl chloride.

The supporting substrate may have a single layer or a plurality of layers, and in general preferably has a thickness of about 5 to 500 μm.

In order to enhance the adhesiveness to the adhesive layer, the supporting substrate can be subjected to surface treatments including, for example, corona discharge treatment, plasma treatment, blasting treatment, chemical etching treatment, and priming treatment.

### [Adhesive Layer]

The present invention is characterized by the use of the adhesive layer containing a side-chain crystalline polymer, the adhesive layer exhibiting an adhesive force when the side-chain crystalline polymer has fluidity at a melting point of the side-chain crystalline polymer or higher and the adhesive force of the adhesive layer being reduced when the side-chain crystalline polymer crystallizes at a temperature lower than the melting point of the side-chain crystalline polymer.

The melting point of the side-chain crystalline polymer as used herein means a temperature at which a specific portion of a polymer first arranged to have an ordered array is turned into a disordered state by an equilibrium process. Further, the melting point is a value obtained by measurement under a measurement condition of 10° C./min using a differential scanning calorimeter (DSC).

<Side-Chain Crystalline Polymer>

Each of the solder transfer sheets described in Patent Literatures 1 and 2 is manufactured while heating the substrate to around 40 to 70° C. in order to firmly fix the solder powder to the adhesive layer in the solder powder adhesion step.

Therefore, according to the invention, from the viewpoint of enhancing adhesiveness in the foregoing temperature range, the side-chain crystalline polymer included in the adhesive layer preferably has a melting point of 40° C. or higher but lower than 70° C. This is because the side-chain crystalline polymer having a melting point in the temperature range of 40° C. or higher but lower than 70° C. is melted in the solder powder adhesion step allow the adhesive layer to easily exhibit adhesiveness.

The solder powder adhesion step is performed while heating the substrate to around 40 to 70° C. as described above but the substrate is cooled by around 10° C. after the solder powder adhesion step. At the time of the cooling, side chains of the side-chain crystalline polymer crystallize to allow the solder powder having adhered to the adhesive layer to be held more firmly.

Therefore, according to the invention, the side-chain crystalline polymer preferably has a melting point in the temperature range of 40° C. or higher but lower than 70° C.

An example of the side-chain crystalline polymer satisfying such characteristics includes a copolymer obtained by polymerizing 30 to 60 parts by weight of an acrylic acid ester or methacrylic acid ester having a straight-chain alkyl group containing 18 or more carbon atoms, 45 to 65 parts by weight of an acrylic acid ester or methacrylic acid ester having an alkyl group containing 1 to 6 carbon atoms, and 1 to 10 parts by weight of a polar monomer.

Examples of the acrylic acid ester or methacrylic acid ester having a straight-chain alkyl group containing 18 or more carbon atoms include hexadecyl (meth)acrylate, stearyl (meth)acrylate, and docosyl (meth)acrylate. These may be used singly or in combination of two or more.

In the specification, (meth)acrylate is a concept including both methacrylate and acrylate.

Examples of the acrylic acid ester or methacrylic acid ester having an alkyl group containing 1 to 6 carbon atoms include methyl (meth)acrylate, ethyl acrylate, butyl (meth)acrylate, isobutyl (meth)acrylate, t-butyl (meth)acrylate, hexyl (meth)acrylate, cyclohexyl (meth)acrylate, and isoamyl (meth)acrylate. These may be used singly or in combination of two or more.

The polar monomer refers to a monomer having a polar functional group (e.g., carboxyl group, hydroxyl group, amide group, amino group, epoxy group or the like) and specific examples thereof include carboxyl group-containing ethylenically unsaturated monomers such as acrylic acid, methacrylic acid, crotonic acid, itaconic acid, maleic acid and fumaric acid; and hydroxyl group-containing ethylenically unsaturated monomers such as 2-hydroxyethyl (meth)acrylate, 2-hydroxypropyl (meth)acrylate, and 2-hydroxyhexyl (meth)acrylate. These may be used singly or in combination of two or more.

According to the invention, the side-chain crystalline polymer preferably has a weight-average molecular weight of 200,000 to 1,000,000.

The sheet release properties are better at a weight-average molecular weight of 200,000 or more, whereas the solder powder holding properties are better at a weight-average molecular weight of 1,000,000 or less. From these points of view, the weight-average molecular weight is more preferably 600,000 to 800,000.

The weight-average molecular weight is a polystyrene equivalent value measured by gel permeation chromatography (GPC).

According to the invention, at the melting point of the side-chain crystalline polymer or higher, the adhesive layer preferably has an adhesive force of 2.0 N/25 mm to 10.0 N/25 mm, more preferably 2.5 N/25 mm to 9.0 N/25 mm, and even more preferably 6.0 N/25 mm to 8.0 N/25 mm.

The adhesive force of the adhesive layer as used herein refers to an adhesive force with respect to an plate (stainless steel plate) as measured at 80° C. according to JIS Z 0237.

The solder powder holding properties are better at an adhesive force of the adhesive layer in a range of 2.0 N/25 mm or more, whereas the sheet release properties are better at an adhesive force of the adhesive layer in a range of 10.0 N/25 mm or less.

On the other hand, at a temperature lower than the melting point of the side-chain crystalline polymer, the adhesive layer preferably has an adhesive force of less than 2.0 N/25 mm, and more preferably 1.5 N/25 mm or less.

The adhesive force of the adhesive layer as used herein refers to an adhesive force with respect to an SUS plate (stainless steel plate) as measured at 23° C. according to JIS Z 0237.

The sheet release properties are better at an adhesive force of the adhesive layer in a range of less than 2.0 N/25 mm.

According to the invention, in a temperature range of the melting point of the side-chain crystalline polymer or higher, preferably in a temperature range of 200° C. to 230° C., the adhesive layer preferably has a storage modulus of 1×10⁴ to 1×10⁶ Pa, and more preferably 1×10⁴ to 1×10⁵ Pa.

The storage modulus values of the adhesive layer are measured using measurement conditions and samples shown in Examples to be described later.

The sheet release properties are better at a storage modulus of the adhesive layer in a range of 1×10⁴ Pa or more, whereas the solder transfer properties are better at a storage modulus of the adhesive layer in a range of 1×10⁶ Pa or less.

<Crosslinking Agent>

The adhesive layer preferably further contains a crosslinking agent.

Examples of the crosslinking agent include an isocyanate compound, an aziridine compound, an epoxy compound, and a metal chelate compound. These may be used singly or in combination of two or more.

<Method of Preparing Adhesive Layer>

In order to form the above-described adhesive layer on at least one surface of the above-described supporting substrate, for example, a coating solution which makes up the adhesive layer and is obtained by adding an adhesive to a solvent need only be applied to at least one surface the supporting substrate by a coater or the like and be dried.

Various additives including, for example, crosslinking agent, a tackifier, a plasticizer, an antioxidant, and a UV absorber can be added to the coating solution.

Examples of the coater include a knife coater, a roll coater, a calendar coater, a comma coater, gravure coater, and a rod coater.

The adhesive layer preferably has a thickness of 5 to 60 μm, more preferably 5 to 50 μm and even more preferably 5 to 40 μm.

### [Solder Layer]

As in Patent Literatures 1 and 2, the solder layer is a layer having one or more solder particle layers and may be a continuous solder alloy coating.

Such a solder layer can be formed by a solder powder adhesion step described below.

The solder powder adhesion step includes, for example, placing a supporting substrate having an adhesive layer formed thereon on a hot plate at 80° C. which is equal to or higher than the melting point of the side-chain crystalline polymer, sprinkling a surface of the adhesive layer with solder powder, uniformly dispersing the solder powder using an electrostatic brush and a puff to remove excess powder and taking out the supporting substrate from the hot plate.

### [Mode of Use of Solder Transfer Sheet]

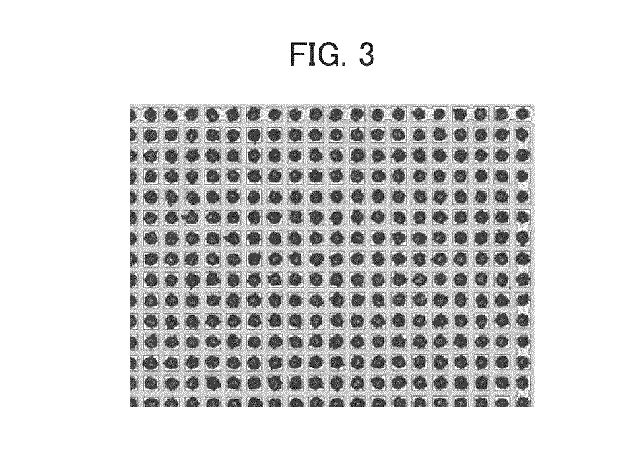

Solder transfer using the solder transfer sheet is performed, for example, as follows: The solder transfer sheet is applied to a transfer target in a state in which the solder layer of the solder transfer sheet faces surfaces of electrodes of the transfer target (e.g., see FIG. 3(a) of Patent Literature 2); a cushion material is placed on a lower surface plate of a hot press set at 40° C.; the transfer target attached to the solder transfer sheet is placed on the cushion material in a state in which the transfer target forms an upper surface; and a pressure of 0 to 5 MPa is applied using an upper surface plate of the hot press set at around a solder powder melting temperature to transfer solder from the solder transfer sheet to the surfaces of the electrodes of the transfer target.

The solder transfer sheet is peeled off, for example, as follows: The pressure of 0 to 5 MPa is applied using the upper surface plate of the hot press set at around the solder powder melting temperature; then the upper surface plate is cooled to a set temperature of 100° C. while the pressure of the same value is continuously applied; the pressure is released to take out the transfer target attached to the solder powder-containing transfer sheet; and the solder powder-containing transfer sheet cooled to room temperature is peeled off from the transfer target.

### EXAMPLES

The present invention is described below in further detail by way of examples.

First, a side-chain crystalline polymer was prepared as described below.

In the following, the term “parts” means parts by weight. Behenyl acrylate and/or stearyl acrylate was used as the acrylic acid ester or methacrylic acid ester having a straight-chain alkyl group containing 18 or more carbon atoms, methyl acrylate was used as the acrylic acid ester or methacrylic acid ester having an alkyl group containing 1 to 6 carbon atoms, and acrylic acid was used as the polar monomer.

### A. Preparation of Side-Chain Crystalline Polymer

### Synthesis Example 1

Behenyl acrylate (65 parts), methyl acrylate (30 parts), acrylic acid (5 parts) and PERBUTYL ND (manufactured by NOF Corporation; 0.3 part) were added to ethyl acetate (230 parts) and mixed. The mixture was stirred at 55° C. for 4 hours. Then, the temperature was raised to 80° C. and PERHEXYL PV (manufactured by NOF Corporation; 0.5 part) was added. The mixture was stirred for 2 hours to polymerize these monomers. The resulting polymer had a weight-average molecular weight of 750,000 and a melting point of 59° C.

### Synthesis Example 2

Behenyl acrylate (45 parts), methyl acrylate (50 parts), acrylic acid (5 parts) and PERBUTYL ND (manufactured by NOF Corporation; 0.3 part) were added to ethyl acetate (230 parts) and mixed. The mixture was stirred at 55° C. for 4 hours. Then, the temperature was raised to 80° C. and PERHEXYL PV (manufactured by NOF Corporation; 0.5 part) was added. The mixture was stirred for 2 hours to polymerize these monomers. The resulting polymer had a weight-average molecular weight of 650,000 and a melting point of 54° C.

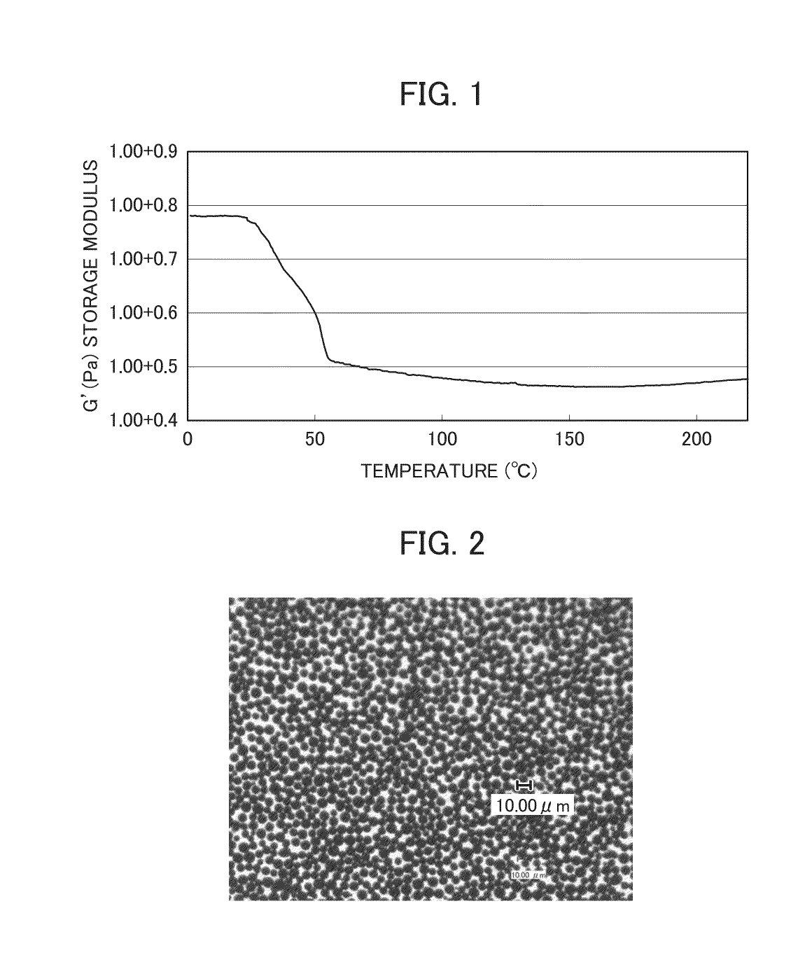

A relationship between the temperature of the side-chain crystalline polymer synthesized in Synthesis Example 2 and the storage modulus of the adhesive is illustrated in FIG. 1.

### Synthesis Example 3

Behenyl acrylate (35 parts), methyl acrylate (60 parts), acrylic acid (5 parts) and PERBUTYL ND (manufactured by NOF Corporation; 0.3 part) were added to ethyl acetate (230 parts) and mixed. The mixture was stirred at 55° C. for 4 hours. Then, the temperature was raised to 80° C. and PERHEXYL PV (manufactured by NOF Corporation; 0.5 part) was added. The mixture was stirred for 2 hours to polymerize these monomers. The resulting polymer had a weight-average molecular weight of 680,000 and a melting point of 50° C.

### Synthesis Example 4

Behenyl acrylate (35 parts), methyl acrylate (60 parts), acrylic acid (5 parts) and PERBUTYL ND (manufactured by NOF Corporation; 0.5 part) were added to toluene (230 parts) and mixed. The mixture was stirred at 65° C. for 4 hours. Then, PERHEXYL PV (manufactured by NOF Corporation; 0.5 part) was added. The mixture was stirred for 2 hours to polymerize these monomers. The resulting polymer had a weight-average molecular weight of 180,000 and a melting point of 50° C.

### Synthesis Example 5

Behenyl acrylate (35 parts), methyl acrylate (60 parts), acrylic acid (5 parts) and PERBUTYL ND (manufactured by NOF Corporation; 0.1 part) were added to ethyl acetate (180 parts) and mixed. The mixture was stirred at 55° C. for 4 hours. Then, the temperature was raised to 80° C. and PERHEXYL PV (manufactured by NOF Corporation; 0.5 part) was added. The mixture was stirred for 2 hours to polymerize these monomers. The resulting polymer had a weight-average molecular weight of 1,050,000 and a melting point of 51° C.

### Synthesis Example 6

Behenyl acrylate (25 parts), methyl acrylate (70 parts), acrylic acid (5 parts) and PERBUTYL ND (manufactured by NOF Corporation; 0.3 part) were added to ethyl acetate/heptane (7:3; 230 parts) and mixed. The mixture was stirred at 55° C. for 4 hours. Then, the temperature was raised to 80° C. and PERHEXYL PV (manufactured by NOF Corporation; 0.5 part) was added. The mixture was stirred for 2 hours to polymerize these monomers. The resulting polymer had a weight-average molecular weight of 600,000 and a melting point of 38° C.

### Synthesis Example 7

Behenyl acrylate (30 parts), stearyl acrylate (15 parts), methyl acrylate (50 parts), acrylic acid (5 parts) and PERBUTYL ND (manufactured by NOF Corporation; 0.3 part) were added to ethyl acetate (230 parts) and mixed. The mixture was stirred at 55° C. for 4 hours. Then, the temperature was raised to 80° C. and PERHEXYL PV (manufactured by NOF Corporation; 0.5 part) was added. The mixture was stirred for 2 hours to polymerize these monomers. The resulting polymer had a weight-average molecular weight of 520,000 and a melting point of 47° C.

### Synthesis Example 8

Behenyl acrylate (20 parts), stearyl acrylate (15 parts), methyl acrylate (60 parts), acrylic acid (5 parts) and PERBUTYL ND (manufactured by NOF Corporation; 0.3 part) were added to ethyl acetate (230 parts) and mixed. The mixture was stirred at 55° C. for 4 hours. Then, the temperature was raised to 80° C. and PERHEXYL PV (manufactured by NOF Corporation; 0.5 part) was added. The mixture was stirred for 2 hours to polymerize these monomers. The resulting polymer had a weight-average molecular weight of 600,000 and a melting point of 41° C.

### Synthesis Example 9

Behenyl acrylate (25 parts), methyl acrylate (70 parts), acrylic acid (5 parts) and PERBUTYL ND (manufactured by NOF Corporation; 0.3 part) were added to toluene (230 parts) and mixed. The mixture was stirred at 55° C. for 4 hours. Then, the temperature was raised to 80° C. and PERHEXYL PV (manufactured by NOF Corporation; 0.5 part) was added. The mixture was stirred for 2 hours to polymerize these monomers. The resulting polymer had a weight-average molecular weight of 170,000 and a melting point of 37° C.

### Synthesis Example 10

Behenyl acrylate (30 parts), methyl acrylate (65 parts), acrylic acid (5 parts) and PERBUTYL ND (manufactured by NOF Corporation; 0.1 part) were added to ethyl acetate (230 parts) and mixed. The mixture was stirred at 55° C. for 4 hours. Then, the temperature was raised to 80° C. and PERHEXYL PV (manufactured by NOF Corporation; 0.5 part) was added. The mixture was stirred for 2 hours to polymerize these monomers. The resulting polymer had a weight-average molecular weight of 900,000 and a melting point of 46° C.

### Synthesis Example 11

Behenyl acrylate (50 parts), methyl acrylate (45 parts), acrylic acid (5 parts) and PERBUTYL ND (manufactured by NOF Corporation; 0.3 part) were added to ethyl acetate (250 parts) and mixed. The mixture was stirred at 55° C. for 4 hours. Then, the temperature was raised to 80° C. and PERHEXYL PV (manufactured by NOF Corporation; 0.5 part) was added. The mixture was stirred for 2 hours to polymerize these monomers. The resulting polymer had a weight-average molecular weight of 320,000 and a melting point of 55° C.

The composition ratio of the monomer ingredients, and the results of the melting point and the weight-average molecular weight of the synthesized side-chain crystalline polymers are shown in Table 1.

The melting point was measured under a measurement condition of 10° C./min using a differential scanning calorimeter (DSC) and the weight-average molecular weight was a polystyrene equivalent value obtained from a value measured by gel permeation chromatography (GPC).

TABLE 1

| | | | Weight-average |
|---|---|---|---|
| | Monomer composition/ | Melting point | molecular |
| | ratio | (° C.) | weight |
| Synthesis | C22A/C1A/AA = | 59 | 750,000 |
| Example 1 | 65/30/5 | | |
| Synthesis | C22A/C1A/AA = | 54 | 650,000 |
| Example 2 | 45/50/5 | | |
| Synthesis | C22A/C1A/AA = | 50 | 680,000 |
| Example 3 | 35/60/5 | | |
| Synthesis | C22A/C1A/AA = | 50 | 180,000 |
| Example 4 | 35/60/5 | | |
| Synthesis | C22A/C1A/AA = | 51 | 1,050,000 |
| Example 5 | 35/60/5 | | |
| Synthesis | C22A/C1A/AA = | 38 | 600,000 |
| Example 6 | 25/70/5 | | |
| Synthesis | C22A/C18A/C1A/AA = | 47 | 520,000 |
| Example 7 | 30/15/50/5 | | |
| Synthesis | C22A/C18A/C1A/AA = | 41 | 600,000 |
| Example 8 | 20/15/60/5 | | |
| Synthesis | C22A/C1A/AA = | 37 | 170,000 |
| Example 9 | 25/70/5 | | |
| Synthesis | C22A/C1A/AA = | 46 | 900,000 |
| Example 10 | 30/65/5 | | |
| Synthesis | C22A/C1A/AA = | 55 | 320,000 |
| Example 11 | 50/45/5 | | |

C22A: Behenyl acrylate
C18A: Stearyl acrylate
C1A: Methyl acrylate
AA: Acrylic acid

### B. Preparation of Adhesive Layer-Bearing Supporting Substrate Sheet

### Example 1

A solvent (ethyl acetate) was used in the polymer solution obtained in Synthesis Example 1 to adjust the solid content concentration to 25%. CHEMITITE PZ-33 (manufactured by Nippon Shokubai Co., Ltd.) was added to the polymer solution as a crosslinking agent in an amount of 0.2 part with respect to 100 parts of the polymer and the resulting polymer solution was applied to a corona-treated surface of a 100 μm polyethylene terephthalate (PET) film by a comma coater to obtain a supporting substrate having an acrylic adhesive layer (40 μm).

### Example 2

A solvent (ethyl acetate) was used in the polymer solution obtained in Synthesis Example 2 to adjust the solid content concentration to 25%. CHEMITITE PZ-33 (manufactured by Nippon Shokubai Co., Ltd.) was added to the polymer solution as a crosslinking agent in an amount of 0.2 part with respect to 100 parts of the polymer and the resulting polymer solution was applied to a corona-treated surface of a 100 μm polyethylene terephthalate (PET) film by a comma coater to obtain a supporting substrate having an acrylic adhesive layer (40 μm).

### Example 3

A solvent (ethyl acetate) was used in the polymer solution obtained in Synthesis Example 3 to adjust the solid content concentration to 25%. CHEMITITE PZ-33 (manufactured by Nippon Shokubai Co., Ltd.) was added to the polymer solution as a crosslinking agent in an amount of 0.2 part with respect to 100 parts of the polymer and the resulting polymer solution was applied to a corona-treated surface of a 100 μm polyethylene terephthalate (PET) film by a comma coater to obtain a supporting substrate having an acrylic adhesive layer (40 μm).

### Example 4

A solvent (ethyl acetate) was used in the polymer solution obtained in Synthesis Example 4 to adjust the solid content concentration to 25%. CHEMITITE PZ-33 (manufactured by Nippon Shokubai Co., Ltd.) was added to the polymer solution as a crosslinking agent in an amount of 0.2 part with respect to 100 parts of the polymer and the resulting polymer solution was applied to a corona-treated surface of a 100 μm polyethylene terephthalate (PET) film by a comma coater to obtain a supporting substrate having an acrylic adhesive layer (40 μm).

### Example 5

A solvent (ethyl acetate) was used in the polymer solution obtained in Synthesis Example 5 to adjust the solid content concentration to 25%. CHEMITITE PZ-33 (manufactured by Nippon Shokubai Co., Ltd.) was added to the polymer solution as a crosslinking agent in an amount of 0.2 part with respect to 100 parts of the polymer and the resulting polymer solution was applied to a corona-treated surface of a 100 μm polyethylene terephthalate (PET) film by a comma coater to obtain a supporting substrate having an acrylic adhesive layer (40 μm).

### Example 6

A solvent (ethyl acetate) was used in the polymer solution obtained in Synthesis Example 6 to adjust the solid content concentration to 25%. CHEMITITE PZ-33 (manufactured by Nippon Shokubai Co., Ltd.) was added to the polymer solution as a crosslinking agent in an amount of 0.2 part with respect to 100 parts of the polymer and the resulting polymer solution was applied to a corona-treated surface of a 100 μm polyethylene terephthalate (PET) film by a comma coater to obtain a supporting substrate having an acrylic adhesive layer (40 μm).

### Example 7

A solvent (ethyl acetate) was used in the polymer solution obtained in Synthesis Example 7 to adjust the solid content concentration to 25%. CHEMITITE PZ-33 (manufactured by Nippon Shokubai Co., Ltd.) was added to the polymer solution as a crosslinking agent in an amount of 0.2 part with respect to 100 parts of the polymer and the resulting polymer solution was applied to a corona-treated surface of a 100 μm polyethylene terephthalate (PET) film by a comma coater to obtain a supporting substrate having an acrylic adhesive layer (40 μm).

### Example 8

A solvent (ethyl acetate) was used in the polymer solution obtained in Synthesis Example 8 to adjust the solid content concentration to 25%. CHEMITITE PZ-33 (manufactured by Nippon Shokubai Co., Ltd.) was added to the polymer solution as a crosslinking agent in an amount of 0.2 part with respect to 100 parts of the polymer and the resulting polymer solution was applied to a corona-treated surface of a 100 μm polyethylene terephthalate (PET) film by a comma coater to obtain a supporting substrate having an acrylic adhesive layer (40 μm).

### Example 9

A solvent (ethyl acetate) was used in the polymer solution obtained in Synthesis Example 9 to adjust the solid content concentration to 25%. CHEMITITE PZ-33 (manufactured by Nippon Shokubai Co., Ltd.) was added to the polymer solution as a crosslinking agent in an amount of 0.2 part with respect to 100 parts of the polymer and the resulting polymer solution was applied to a corona-treated surface of a 100 μm polyethylene terephthalate (PET) film by a comma coater to obtain a supporting substrate having an acrylic adhesive layer (40 μm).

### Example 10

A solvent (ethyl acetate) was used in the polymer solution obtained in Synthesis Example 10 to adjust the solid content concentration to 25%. CHEMITITE PZ-33 (manufactured by Nippon Shokubai Co., Ltd.) was added to the polymer solution as a crosslinking agent in an amount of 0.2 part with respect to 100 parts of the polymer and the resulting polymer solution was applied to a corona-treated surface of a 100 μm polyethylene terephthalate (PET) film by a comma coater to obtain a supporting substrate having an acrylic adhesive layer (40 μm).

### Example 11

A solvent (ethyl acetate) was used in the polymer solution obtained in Synthesis Example 11 to adjust the solid content concentration to 25%. CHEMITITE PZ-33 (manufactured by Nippon Shokubai Co., Ltd.) was added to the polymer solution as a crosslinking agent in an amount of 0.2 part with respect to 100 parts of the polymer and the resulting polymer solution was applied to a corona-treated surface of a 100 μm polyethylene terephthalate (PET) film by a comma coater to obtain a supporting substrate having an acrylic adhesive layer (40 μm).

### Example 12

An adhesive tape (product name: SBHF-75; manufactured by Unon-Giken Co., Ltd.) using an amorphous polymer was used.

### C. Preparation of Solder Transfer Sheet

Each adhesive layer-bearing supporting substrate obtained above was used to prepare a solder transfer sheet as described below.

To be more specific, the solder transfer sheet was obtained by a method which involves placing an adhesive layer-bearing supporting substrate on a hot plate at 60 to 80° C., sprinkling the supporting substrate with solder powder of SAC305 (containing 3 wt % of Ag, 0.5 wt % of Cu, and a balance of Sn) having a powder particle size of 1 to 10 μm, uniformly dispersing the solder powder using an electrostatic brush and a puff to remove excess powder, and taking out the supporting substrate from the hot plate.

An electron micrograph of a solder layer surface of the solder transfer sheet prepared in Example 2 is illustrated in FIG. 2.

### [Evaluation]

Each of the prepared adhesive layer-bearing supporting substrate sheets was subjected to tests for measuring the adhesive force and the storage modulus of the adhesive layer according to methods described below.

Each of the prepared solder transfer sheets was also evaluated for the solder powder holding properties, the sheet release properties and the solder transfer properties according to methods described below. The result of a solder transfer test using the solder transfer sheet prepared in Example 2 (the state in which solder is only transferred onto electrodes of silicon wafer chips) is illustrated in FIG. 3.

These results are shown in Table 2.

<Adhesive Force>

Adhesive force test: This test was performed in two environments of 80° C. and 23° C. according to the following procedure.

1. The adhesion strength of the adhesive was measured with respect to SUS according to JIS Z 0237. Measurement was performed at two temperatures including: i) 80° C.; and ii) 23° C. to which the temperature was decreased after being once increased to 220° C. It should be noted that the adhesive force in Table 2 is an average value when n is 3.

<Storage Modulus>

Storage modulus test: The storage modulus test was performed in two environments of 220° C. and 23° C. according to the following procedure.

(Measurement conditions): Oscillation strain control: 0.2%; frequency: 1 Hz; measurement temperature: 0 to 250° C.; temperature elevation rate: 5° C./min; plate: SUS plate with a diameter of 20 mm.

A sample having an adhesive layer formed to a thickness of about 800 μm was prepared and punching was performed to have a diameter of 20 mm. The sample was subjected to measurement using a stress controlled rheometer RheoPolym@(manufactured by Reologica) under the above-described conditions and G′ values at 220° C. and 23° C. were adopted as storage modulus values.

<Solder Powder Holding Properties>

Test of solder powder holding properties: The test of solder powder holding properties was performed according to the following procedure.

1. An adhesive sheet is placed on a hot plate at 60 to 80° C.; a surface of the adhesive sheet is sprinkled with solder powder; the solder powder is uniformly dispersed using an electrostatic brush and a puff to remove excess powder; and the supporting substrate is taken out from the hot plate.

2. The filling ratio of the solder powder is measured by a microscope through binarization to check the holding properties.

3. A filling ratio of 70% or more was rated as Pass and a filling ratio of less than 70% was rated as Fail.

<Sheet Release Properties>

Test of release properties: The test of release properties was performed in an environment of 23° C. according to the following procedure.

1. A solder surface of a solder powder-containing transfer sheet is opposed to electrode surfaces (diameter: 20 μm) of silicon wafer chips arranged in a lattice at a pitch of 50 μm. The transfer sheet and the silicon wafer chips are heated and pressurized by a hot press at 220 to 225° C. and 1 MPa, and cooled to 100° C. Then, the pressure is released, and the transfer sheet and the silicon wafer chips are taken out.

2. The solder-containing transfer sheet is peeled off from the silicon wafer chips at a temperature lower than the melting point of the side-chain crystalline polymer contained in the adhesive layer to check the adhesive remaining on the silicon wafer chips.

3. A residual adhesive ratio ([area where the adhesive remains/electrode area of 5 square millimeters]×100%) of less than 10% was rated as Pass and a residual adhesive ratio of 10% or more was rated as Fail.

<Solder Transfer Properties>

Test of solder transfer properties: The test of solder transfer properties was performed in an environment of 220° C. according to the following procedure.

1. A solder surface of a solder powder-containing transfer sheet is opposed to electrode surfaces (diameter: 20 μm) of silicon wafer chips arranged in a lattice at a pitch of 50 μm. The transfer sheet and the silicon wafer chips are heated and pressurized by a hot press at 220 to 225° C. and 1 MPa, and cooled to 100° C. Then, the pressure is released, and the transfer sheet and the silicon wafer chips are taken out.

2. The solder-containing transfer sheet is peeled off from the silicon wafer chips at a temperature lower than the melting point of the side-chain crystalline polymer contained in the adhesive layer to check the properties of the solder transfer to the electrodes of the silicon wafer chips.

3. A number of bridges between the silicon wafer chip electrodes of less than 5 was rated as Pass and a number of bridges between the silicon wafer chip electrodes of 5 or more was rated as Fail.

TABLE 2

| | | Adhesive layer - evaluation | | | | | |
|---|---|---|---|---|---|---|---|
| | | | | | Solder powder | | |
| | | Adhesive | Adhesive | Storage | holding | Sheet release | Solder transfer |
| | Side-chain | force | force | modulus | properties*4 | properties*5 | properties*6 |
| | crystalline | (N/25 mm) | (N/25 mm) | (MPa) | (%) | (%) | (No. of pcs) |
| | polymer | [80° C.] | [23° C.] | [220° C.] | [80° C.] | [23° C.] | [220° C.] |
| Example 1 | Synthesis | 15.0 | 4.4 (AT) *1 | 5.0 × 10³ | 80 | 98 | *3 |
| | Example 1 | | | | | | |
| Example 2 | Synthesis | 7.1 | 1.2 | 3.0 × 10⁴ | 78 | 0 | 0 |
| | Example 2 | | | | | | |
| Example 3 | Synthesis | 6.5 | 0.8 | 5.0 × 10⁴ | 75 | 0 | 0 |
| | Example 3 | | | | | | |
| Example 4 | Synthesis | 14.0 | 6.0 (SS) *2 | 1.0 × 10³ | 82 | 100 | *3 |
| | Example 4 | | | | | | |
| Example 5 | Synthesis | 1.5 | 0.6 | 1.0 × 10⁷ | 63 | 0 | 5≧ |
| | Example 5 | | | | | | |
| Example 6 | Synthesis | 1.8 | 0.8 | 5.0 × 10⁶ | 64 | 0 | 5≧ |
| | Example 6 | | | | | | |
| Example 7 | Synthesis | 7.5 | 1.5 | 2.0 × 10⁴ | 79 | 0 | 0 |
| | Example 7 | | | | | | |
| Example 8 | Synthesis | 7.0 | 1.2 | 3.0 × 10⁴ | 78 | 0 | 0 |
| | Example 8 | | | | | | |
| Example | Synthesis | 11.0 | 4.0 | 8.0 × 10³ | 80 | 95 | *3 |
| | Example 9 | | | | | | |
| Example 10 | Synthesis | 2.5 | 0.9 | 1.0 × 10⁶ | 75 | 0 | 0 |
| | Example 10 | | | | | | |
| Example 11 | Synthesis | 9.0 | 1.9 | 1.0 × 10⁴ | 79 | 0 | 0 |
| | Example 11 | | | | | | |
| Example 12 | Amorphous | 14.7 | 20≧ | 2.0 × 10³ | 81 | 100 | *3 |
| | polymer | | | | | | |

*1: “AT” refers to a peeled state indicating transfer.
*2: “SS” refers to a peeled state indicating slip sticking.
*3: At the time of the test of release properties (evaluation of the sheet release properties), a large part of the adhesive layer remains on the silicon wafer chips and the solder transfer properties cannot be correctly evaluated.
*4The filling ratio of the solder powder on the adhesive sheet is shown, and a filling ratio of 70% or more was rated as Pass and a filling ratio of less than 70% was rated as Fail.
*5The residual adhesive ratio within a silicon wafer chip electrode area of 5 square millimeters is shown, and a residual adhesive ratio of less than 10% was rated as Pass and a residual adhesive ratio of 10% or more was rated as Fail.
*6The number of bridges between the silicon wafer chip electrodes is shown, and a number of bridges of less than 5 was rated as Pass and a number of bridges of 5 or more was rated as Fail.

The results shown in Table 1 and Table 2 revealed that, when the adhesive sheet containing the amorphous polymer is used, the sheet release properties are extremely poor and the solder transfer properties also cannot be evaluated (Example 12).

In contrast, it was revealed that, in cases where the adhesive layers each containing the side-chain crystalline polymer are used, the solder powder holding properties and the sheet release properties are achieved simultaneously and the solder transfer properties are excellent when each adhesive layer has an adhesive force of 2.0 N/25 mm to 10.0 N/25 mm at the melting point of the side-chain crystalline polymer or higher, has an adhesive force of less than 2.0 N/25 mm at a temperature lower than the melting point of the side-chain crystalline polymer, and has a storage modulus of 1×10⁴ to 1×10⁶ Pa at the melting point of the side-chain crystalline polymer or higher (Examples 2, 3, 7, 8, 10 and 11).

The results of these examples also revealed that the solder powder holding properties, the sheet release properties and the solder transfer properties are all better when each side-chain crystalline polymer contained in the adhesive layer is a copolymer obtained by polymerizing an acrylic acid ester or methacrylic acid ester having a straight-chain alkyl group having 18 or more carbon atoms at a proportion of 30 to 60 parts by weight, has a melting point of 40° C. or higher but lower than 70° C. and a weight-average molecular weight of 200,000 to 1,000,000.

1-7. (canceled)

8. A solder transfer sheet for soldering on portions of a circuit board to be soldered, the solder transfer sheet comprising:
a supporting substrate; an adhesive layer formed on at least one surface of the supporting substrate; and a solder layer formed on the adhesive layer and having one or more solder particle layers,
wherein the adhesive layer is an adhesive layer having an adhesive force of less than 2.0 N/25 mm at 23° C., and
wherein the adhesive layer is an adhesive layer having an adhesive force of 2.0 N/25 mm to 10.0 N/25 mm at 80° C.

9. A solder transfer sheet for soldering on portions of a circuit board to be soldered, the solder transfer sheet comprising:
a supporting substrate; an adhesive layer formed on at least one surface of the supporting substrate; and a solder layer formed on the adhesive layer and having one or more solder particle layers,
wherein the adhesive layer is an adhesive layer having an adhesive force of less than 2.0 N/25 mm at 23° C., and
wherein the adhesive layer is an adhesive layer containing a side-chain crystalline polymer, the adhesive layer exhibiting an adhesive force at a temperature of 40° C. or higher and the adhesive force of the adhesive layer being reduced at a temperature of lower than 40° C.

10. The solder transfer sheet according to claim 9, wherein the side-chain crystalline polymer is a copolymer obtained by polymerizing 30 to 60 parts by weight of an acrylic acid ester or methacrylic acid ester having a straight-chain alkyl group containing 18 or more carbon atoms, 45 to 65 parts by weight of an acrylic acid ester or methacrylic acid ester having an alkyl group containing 1 to 6 carbon atoms, and 1 to 10 parts by weight of a polar monomer.

11. The solder transfer sheet according to claim 9, wherein the side-chain crystalline polymer has a weight-average molecular weight of 200,000 to 1,000,000.

12. The solder transfer sheet according to claim 8, wherein the adhesive layer has a storage modulus of 1×10⁴ to 1×10⁶ Pa at 40° C. or higher.

13. The solder transfer sheet according to claim 8, wherein solder powder holding properties at 80° C. expressed by solder powder filling ratio is 70% or more.

14. The solder transfer sheet according to claim 8, wherein sheet release properties at 23° C. expressed by residual adhesive ratio is less than 10%.
